(19) United States
(12) Patent Application Publication
(10) Pub. No.: US 2016/0239699 A1
(43) Pub. Date: Aug. 18, 2016

(54) CHIP SCALE SENSING CHIP PACKAGE AND A MANUFACTURING METHOD THEREOF

(71) Applicant: XINTEC INC., Taoyuan City (TW)

(72) Inventors: Shu-Ming CHANG, New Taipei City (TW); Tsang-Yu LIU, Zhubei City (TW); Yen-Shih HO, Kaohsiung City (TW)

(21) Appl. No.: 15/040,280

(22) Filed: Feb. 10, 2016

Related U.S. Application Data
(60) Provisional application No. 62/116,909, filed on Feb. 16, 2015.
(60) Provisional application No. 62/165,710, filed on May 22, 2015.

(51) Int. Cl. G06K 9/00; H01L 21/78; H01L 23/00; H01L 23/498; H01L 23/053

(52) U.S. Cl. CPC G06K 9/0002; H01L 23/49838; H01L 23/053; H01L 23/49894; H01L 24/17; H01L 24/81; H01L 21/78; H01L 2224/16055; H01L 2224/16057; H01L 2224/16225; H01L 2224/81191; H01L 2924/01014; H01L 2924/146

(57) ABSTRACT

An embodiment of this invention provides a chip scale sensing chip package module, comprising a chip scale sensing chip package, having a sensing chip with a first top substrate and a first bottom substrate opposite to the first top substrate, wherein the sensing chip has a sensing device and a plurality of conductive pads adjacent to the first top substrate, and a plurality of conductive structures connected to the conductive pads by a re-distribution layer adjacent to the first bottom surface; a touch plate having a color layer, comprising a base and a spacer formed on the base, wherein the spacer has a cavity with a bottom wall exposing part of the surface of the base and a side wall surrounding the bottom wall; and a first adhesive layer sandwich between the sensing chip and the touch plate to join the first top surface of the sensing chip to the bottom wall of the cavity of the touch plate and surround the sensing chip by the side wall of the cavity; and a print circuit board placed under the chip scale sensing chip package by bonding the conductive structure of the chip scale sensing chip package to the print circuit board.

This application claims the benefit of U.S. Provisional Application No. 62/116,909, filed on Feb. 16, 2015, and U.S. Provisional Application No. 62/165,710, filed on May 22, 2015, and the entirety of which are incorporated by reference herein.

### BACKGROUND OF THE INVENTION

1. Field of the Invention

The present invention relates to a sensing chip package module, and in particular relates to a chip scale sensing chip package module and a manufacturing method thereof.

2. Description of the Related Art

A conventional chip package having sensing functions, such as a fingerprint-recognition chip package, is easily contaminated or damaged during the manufacturing processes which results in decreasing both the yield and liability of conventional chip package having sensing functions. In order to meet the tendency of size-miniaturization of electronic components, it is an import subject to minimize the thickness of a substrate for carrying a semiconductor chip to be packaged. However, if a thin substrate for carrying a semiconductor chip to be packaged is utilized, the yield will be reduced owing to the thin substrate is bended or damaged during the package process.

Moreover, the touch panel or the panel having sensing functions, for example biometric identification, are current trends of technology. However, the touch devices are easily out of orders owing to frequently pressing onto the panel by users. In order to resolve abovementioned defects, a scratch-resistance material having a hardness higher than 9, for example sapphire, is selected as the touch pad of the touch panel to protect the semiconductor devices under the touch panel. Currently, the sapphire substrate used to protect the touch devices or biometric sensing devices has a thickness about 200 μm, and the signals of the touch panel or the sensing panel with biometric identification functions are transmitted by the change of touch pad's capacitance. The capacitance of a parallel plate capacitor is well-known as following formula: C=ε*A/d, wherein C is the capacitance of a parallel plate capacitor, E is the capacitance permittivity of the dielectric material between parallel plates, A is the area of overlap of parallel plates, and d is the distance between the plates. As the capacitance formula of a parallel plate shown, the capacitance is inversely proportional to the distance between the parallel plates when ε and A keep constant. Therefore, the increase of thickness of parallel plates will result in increase of d which leads to decrease of C.

This present invention is achieved by so-called wafer level package processes, which can not only precisely place the thin touch pad on the sensing chip, but also decrease the thickness of the adhesive sandwiched between the touch plate wafer and the wafer with sensing devices by means of spin coating.

Therefore, a low-K material for increasing the capacitance is not necessary and can be replaced by medium-K or low-K materials. Accordingly, the production costs can be reduced, and a chip scale sensing chip package module with higher efficiency are provided. Moreover, the mismatch of the sensing chip and the touch pad occurring in the conventional technologies can be avoided because the touch pad and the chip are of the same chip scale by bonding the touch pad to the sensing chip during the semiconductor process.

### SUMMARY OF THE INVENTION

An embodiment of this invention provide a chip scale sensing chip package module, comprising a chip scale sensing chip package and a print circuit board placed under the chip scale sensing chip package by bonding the conductive structure of the chip scale sensing chip package to the print circuit board. The chip scale sensing chip package comprises a sensing chip with a first top substrate and a first bottom substrate opposite to the first top substrate, wherein the sensing chip has a sensing device and a plurality of conductive pads adjacent to the first top substrate, and a plurality of conductive structures connected to the conductive pads by a re-distribution layer adjacent to the first bottom surface; a touch plate having a color layer comprising a base and a spacer formed on the base, wherein the spacer has a cavity with a bottom wall exposing part of the surface of the base and a side wall surrounding the bottom wall; and a first adhesive layer sandwiched between the sensing chip and the touch plate to adjoin the first top surface of the sensing chip to the bottom wall of the cavity of the touch plate and surround the sensing chip by the side wall of the cavity. The print circuit board is placed under the chip scale sensing chip package by bonding the conductive structure of the chip scale sensing chip package to the print circuit board.

An embodiment of this invention provides another chip scale sensing chip package module, wherein the area of the touch plate is greater than that of the sensing chip.

An embodiment of this invention provides another chip scale sensing chip package module, wherein the top-viewing profile of the cavity is rectangular and the top-viewing profile of the touch plate is circular.

An embodiment of this invention provides another chip scale sensing chip package module, wherein the thickness of the spacer is 10-folds of that of the base.

An embodiment of this invention provides another chip scale sensing chip package module, wherein the color layer is coated on the side wall and the bottom wall of the cavity.

An embodiment of this invention provides another chip scale sensing chip package module, wherein the base and the spacer are consisted of a material comprising glass.

An embodiment of this invention provides another chip scale sensing chip package module, wherein the base comprises a touch plate, a color layer and a second adhesive sandwiched between the touch plate and the color layer, and the spacer is formed on the color layer.

An embodiment of this invention provides another chip scale sensing chip package module, wherein the base and the touch plate are consisted of a material comprising glass, and the spacer is consisted of a material comprising glass or silicon.

An embodiment of this invention provides another chip scale sensing chip package module, wherein the first adhesive is consisted of a low-K or medium-K dielectric material.

An embodiment of this invention provides another chip scale sensing chip package module, wherein the conductive structures are selected from a group of solder balls, solder bumps, and conductive pillars, and mixtures thereof

An embodiment of this invention provides another chip scale sensing chip package module, wherein the sensing device is selected from a group of a touch device, a biometric identification device and an environmental factors sensing device, and mixtures thereof.

An embodiment of this invention provides another chip scale sensing chip package module, wherein the biometric recognition device comprises a fingerprint identification device.

An embodiment of this invention provides another chip scale sensing chip package module, further comprising a buffer apparatus placed on the bottom of the print circuit board.

An embodiment of this invention provides another chip scale sensing chip package module, wherein the buffer apparatus comprises a spring or a spring button.

An embodiment of this invention provides another chip scale sensing chip package module, further comprising a trigger device formed within the cavity of the chip scale sensing chip package and electrically connected to the sensing chip.

An embodiment of this invention provides a method of manufacturing a chip scale sensing chip package module, comprising the steps of providing a plurality of chip scale sensing chips, each chip scale sensing chip comprising a first top substrate and a first bottom substrate opposite to each other, wherein the sensing chip has a sensing device and a plurality of conductive pads adjacent to the first top substrate, and a plurality of conductive structures adjacent to the first bottom surface electrically connected to the conductive pads by a re-distribution layer; providing a touch plate wafer having a color layer and a plurality of bonding areas spaced with scribing lines, and each of the bonding areas having a base and a spacer formed on the base, wherein the spacer has a cavity with a bottom wall exposing part of the surface of the base and a side wall surrounding the bottom wall; and providing an first adhesive layer to join the first top surface of each sensing chip to the bottom wall of each cavity and surround each sensing chip by each side wall of the cavities; applying a scribing process along the scribing lines to generate a plurality of chip scale sensing chip packages, wherein each the chip scale sensing package comprises a sensing chip with a first top substrate and a first bottom substrate opposite to the first top substrate, wherein the sensing chip has a sensing device and a plurality of conductive pads adjacent to the first top substrate, and a plurality of conductive structures connected to the conductive pads by a re-distribution layer adjacent to the first bottom surface; a touch plate having a color layer comprising a base and a spacer formed on the base, wherein the spacer has a cavity with a bottom wall exposing part of the surface of the base and a side wall surrounding the bottom wall; and a first adhesive layer sandwiched between the sensing chip and the touch plate to adjoin the first top surface of the sensing chip to the bottom wall of the cavity of the touch plate and surround the sensing chip by the side wall of the cavity; and providing a print circuit board and bonding one of the chip scale sensing chip packages to the print circuit board by the conductive structures.

An embodiment of this invention provides a method of manufacturing a chip scale sensing chip package module, wherein the area of the touch plate is greater than that of the sensing chip.

An embodiment of this invention provides another method of manufacturing a chip scale sensing chip package module, wherein the top-viewing profile of the cavity is rectangular and the top-viewing profile of the touch plate is circular.

An embodiment of this invention provides another method of manufacturing a chip scale sensing chip package module, wherein the thickness of the spacer is 10-folds of that of the base.

An embodiment of this invention provides another method of manufacturing a chip scale sensing chip package module, wherein the color layer is coated on the side wall and the bottom wall of the cavity.

An embodiment of this invention provides another method of manufacturing a chip scale sensing chip package module, wherein the base and the spacer are consisted of a material comprising glass.

An embodiment of this invention provides another method of manufacturing a chip scale sensing chip package module, wherein the steps of manufacturing the touch plate wafer having a color layer comprise providing a touch plate wafer with a second top surface and a second bottom surface opposite to the second top surface; coating a color layer on the second top surface of the touch plate wafer; coating a second adhesive layer on the color layer; bonding a touch plate to the second adhesive layer; thinning the second bottom surface of the touch plate wafer; and pattering the thinned second bottom surface of the touch plate wafer to form a plurality of bonding areas spaced by scribing lines, and each bonding area comprising a base and a spacer formed on the base, wherein each base has a touch plate, a color layer and a second adhesive layer sandwiched between the touch plate and the color layer, and the spacer is formed on the color layer and has a cavity exposing the color layer.

An embodiment of this invention provides another method of manufacturing a chip scale sensing chip package module, wherein the base and the touch plate are consisted of a material comprising glass, and the spacer is consisted of a material comprising glass or silicon.

An embodiment of this invention provides another method of manufacturing a chip scale sensing chip package module, wherein the first adhesive is consisted of a low-K or medium-K dielectric material.

An embodiment of this invention provides another method of manufacturing a chip scale sensing chip package module, wherein the conductive structures are selected from a group of solder balls, solder bumps, and conductive pillars, and mixtures thereof.

An embodiment of this invention provides another method of manufacturing a chip scale sensing chip package module, wherein the sensing device is selected from a group of a touch device, a biometric identification device and an environmental factors sensing device, and mixtures thereof.

An embodiment of this invention provides another method of manufacturing a chip scale sensing chip package module, wherein the biometric recognition device is a fingerprint identification device.

An embodiment of this invention provides another method of manufacturing a chip scale sensing chip package module, further comprising a step of forming a buffer apparatus on the bottom of the print circuit board.

An embodiment of this invention provides another method of manufacturing a chip scale sensing chip package module, wherein the buffer apparatus comprises a spring or a spring button.

An embodiment of this invention provides another method of manufacturing a chip scale sensing chip package module, further comprising a step of forming a trigger device within the cavity of the chip scale sensing chip package and electrically connected to the sensing chip.

### BRIEF DESCRIPTION OF THE DRAWINGS

The present invention can be more fully understood by reading the subsequent detailed description and examples with references made to the accompanying drawings.

FIGS. 1A˜1E and FIGS. 1C′˜1E′are cross-sectional views of an exemplary embodiment 1 of a method of manufacturing a chip scale sensing chip package module according to this invention.

FIGS. 2A˜2C and FIG. 2B′˜2C′ are cross-sectional views of an exemplary embodiment 2 of a method of manufacturing a chip scale sensing chip package module according to this invention.

FIGS. 3A˜3D are cross-sectional views of a method of manufacturing the bonding areas as shown in FIG. 2A.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. The disclosed contents of the present disclosure include all the embodiments derived from claims of the present disclosure by those skilled in the art. In addition, the present disclosure may repeat reference numbers and/or letters in the various embodiments. This repetition is for the purpose of simplicity and clarity, and does not imply any relationship between the different embodiments and/or configurations discussed. Furthermore, when a first layer is referred to as being on or overlying a second layer, the first layer may be in direct contact with the second layer, or spaced apart from the second layer by one or more material layers.

### Embodiment 1

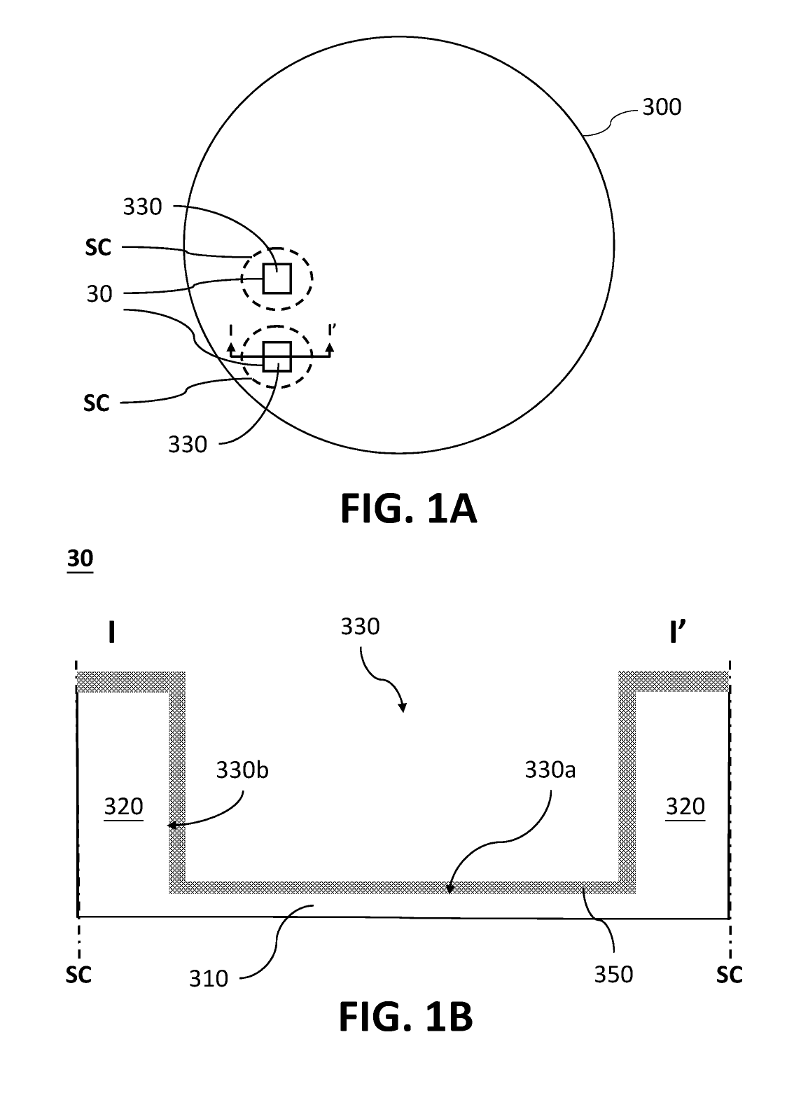

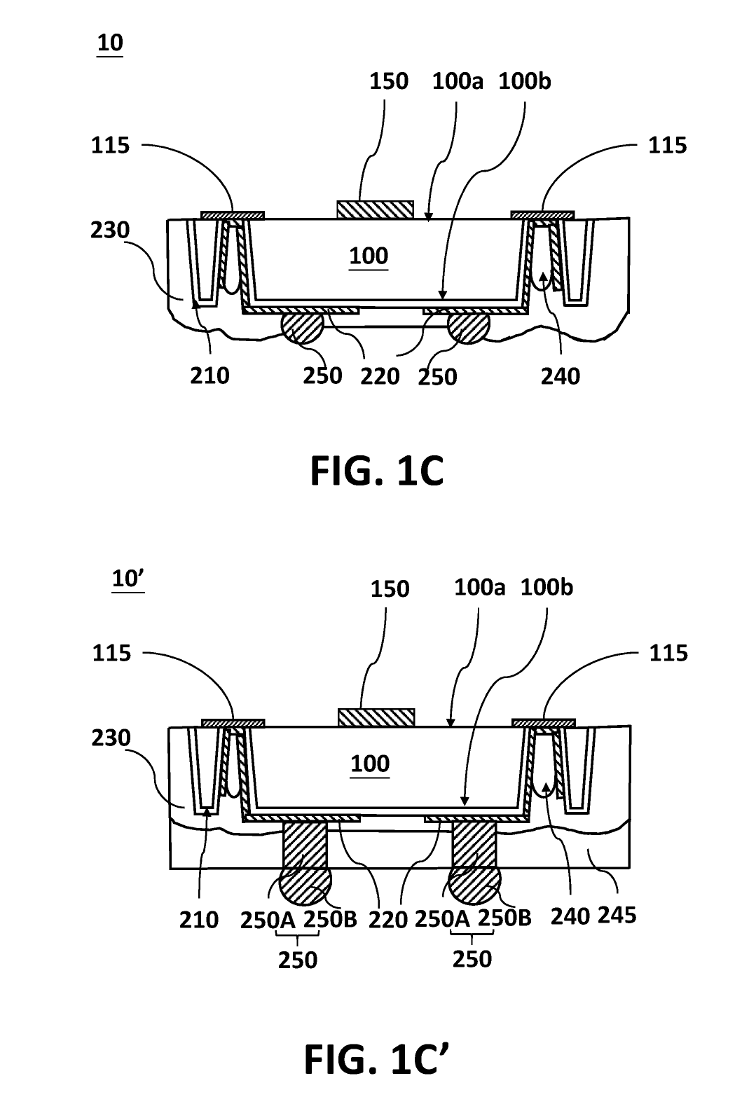

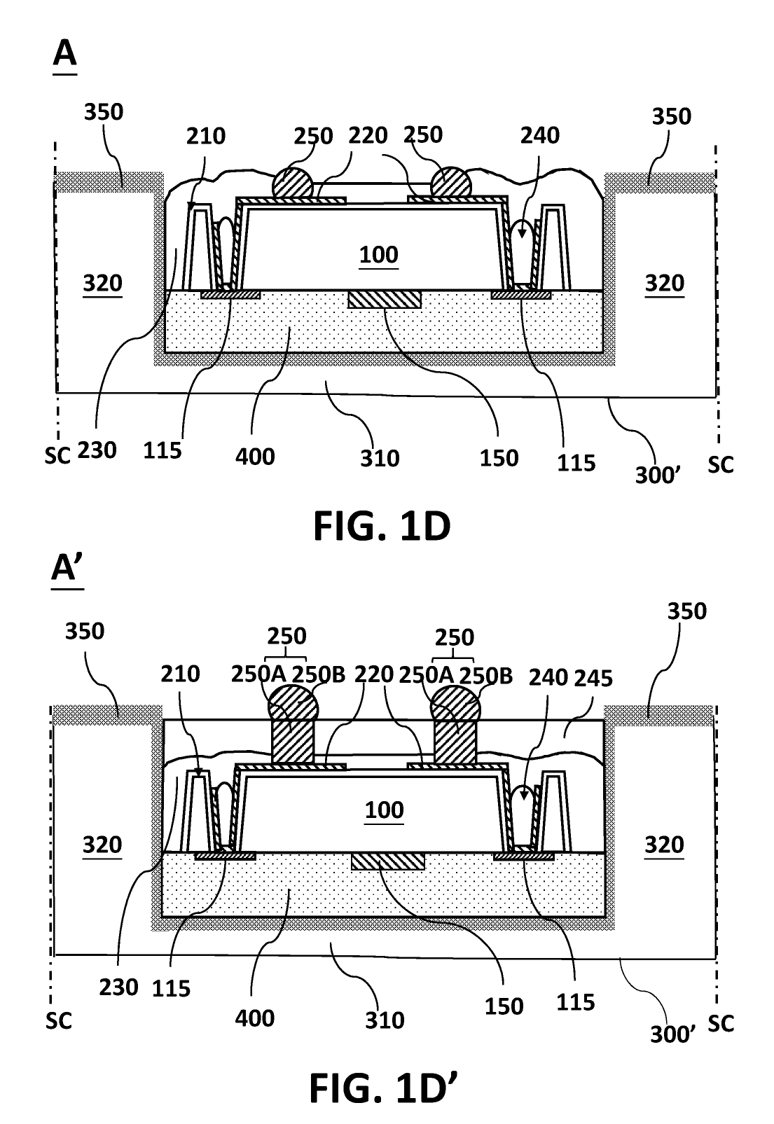

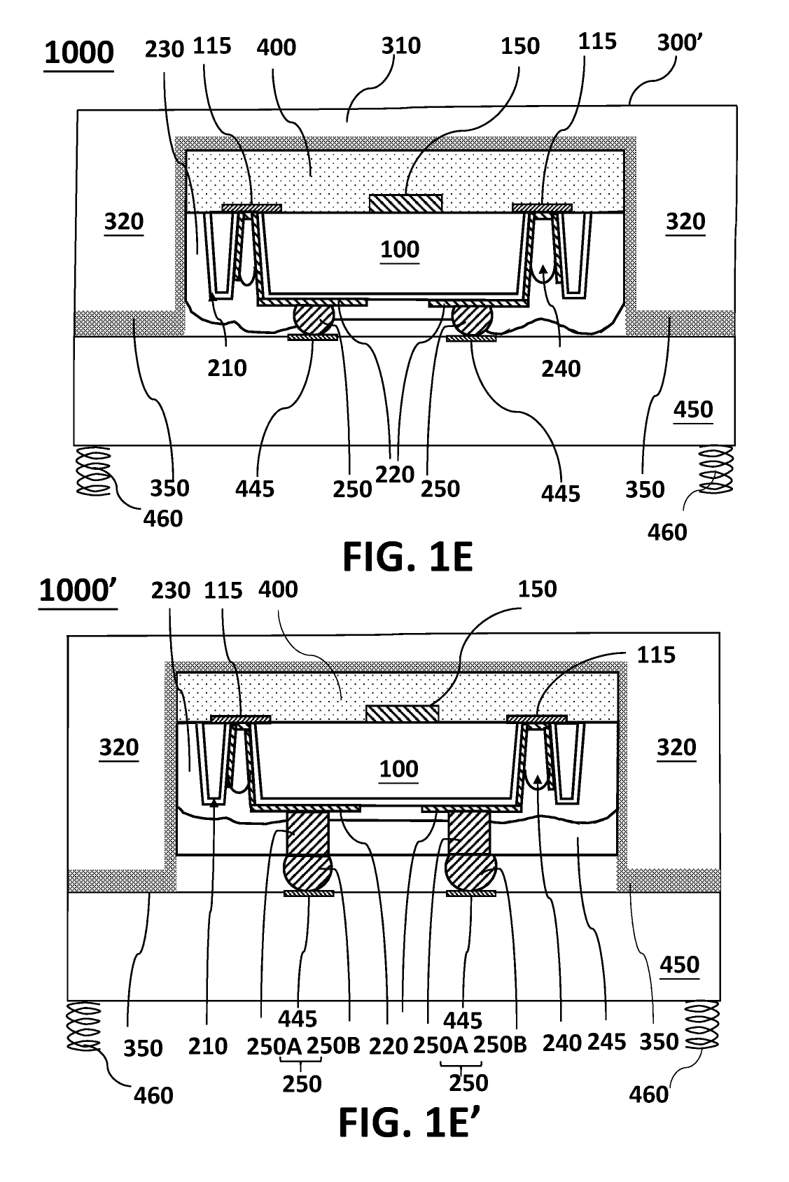

Embodiment 1 disclosing a method of manufacturing a chip scale sensing chip package module according to this invention will be described below and accompanied with FIGS. 1A˜1E and FIGS. 1C′˜1E′.

As shown in FIG. 1A, a touch plate wafer 300 includes a plurality of bonding areas 30 is provided. Each bonding area 30 is surrounded by a circular scribe line SC. The touch plate wafer 300 of this embodiment 1 is consisted of a transparent material with a hardness higher than 7, for example glass.

FIG. 1B is a cross-sectional view of the bonding area 30 along the cross-sectional line I-I′ of FIG. 1A. As shown in FIG. 1B, the bonding area includes a base 310 and a spacer 320 formed on the base 310. The spacer 320 has a cavity 330 exposing the surface of base 310, and the cavity 330 includes a bottom wall 330a and a side wall 330b surrounding the bottom wall 330a. The cavity 330 of this embodiment can be finished by photolithography and etching, milling or molding. The spacer 320 has a thickness 10-folds of that of the base 310. The spacer 320 of this embodiment has a thickness of about 500 μm, and the base 310 of this embodiment has a thickness of about 50 μm. Moreover, a color layer 350 is overlay on the spacer 30 and the bottom wall 330a and side wall 330b of the cavity 330.

Next, a plurality of chip scale sensing chips 10 as shown in FIG. 1C or a plurality of chip scale sensing chips 10′ as shown in FIG. 1C′ is provided. Each chip scale sensing chip 10 or 10′ includes a substrate 100 with a first top surface 100a and a first bottom surface 100b opposite to the first top surface 100b. A sensing device 150 and a plurality of conductive pads 115 are formed adjacent to the first top surface 100a, and a dielectric layer 210, a re-distribution layer (RDL) 220, a passivation layer 230 and conductive structures are formed adjacent to the first bottom surface 100b. The conductive structures 250 is electrically connected to the conductive pads 115 via the re-distribution layer (RDL) 220. The conductive structures 250 of the chip scale sensing chip 10 as shown in FIG. 1C are solder balls. The conductive structures 250 of another embodiments according to this invention can be solder bumps or conductive pillars. Besides, the conductive structures 250 of the chip scale sensing chip 10′ as shown in FIG. 1C′ are consisted of solder balls and conductive pillars, wherein the conductive pillars are gap-filled in the through holes (not shown), penetrating the passivation layer 230 and the molding layer 245 formed on the passivation layer 230, exposing part of the re-distribution layer (RDL) 220, and each solder ball is formed on the molder layer 246 to connect to each conductive pillar. The molding layer 246 of this embodiment is consisted of epoxy and has a thickness of about 100 μm.

Next, referring to FIG. 1D and FIG. 1D′, a first adhesive 400 is coated on the first top surface 100a or the bottom wall 330a of the cavity 300 of the chip scale sensing chip 10 as shown in FIG. 1D or the chip scale sensing chip 10 as shown in FIG. 1D′, and the chip scale sensing chip 10 or 10′ is bonding to the color layer 350 formed on the bottom wall 330a of the cavity 330a locating in each bonding area 30. Moreover, other electronic devices for triggering sensing chips like trigger devices (not shown) can also be bond onto the color layer 350 formed on the bottom wall 330a of the cavity 330a locating in each bonding area 30 and electrically connected the sensing chips 10 or 10′.

Next, scribing the touch plate wafer 300 along the scribing lines SC to generate a plurality of individual chip scale sensing chips A or A′. Each chip scale sensing chips A or A′ includes a sensing chip 100 with a top-view profile of rectangular, and each sensing chip 100 has a sensing device 150 surrounded by a plurality of conductive pads 115 and a touch pad 300′ with a top-view profile of circular including a base 310 and a spacer 320 formed on the base 310, wherein the area of the touch pad 300′ is greater than that of the sensing chip 300.

Finally, a print circuit board 450 with a plurality of conductive bonding pads 445 formed thereon as shown in FIG. 1E and 1E′ is provided. The chip scale sensing chip package A or A′ manufactured by above processes is electrically bonded to the print circuit board 450 via the join of the conductive structures 250 and the conductive bonding pads to generate a chip scale sensing chip package module 1000 or 1000′. Besides, a buffer apparatus 460 like a spring or a spring button can be placed on the bottom of the print circuit board 450 to provide a buffering force which can avoid the defect of the conjunction of the chip scale sensing chip package A or A′ and the print circuit board 450 caused by the pressing force of the user.

### Embodiment 2

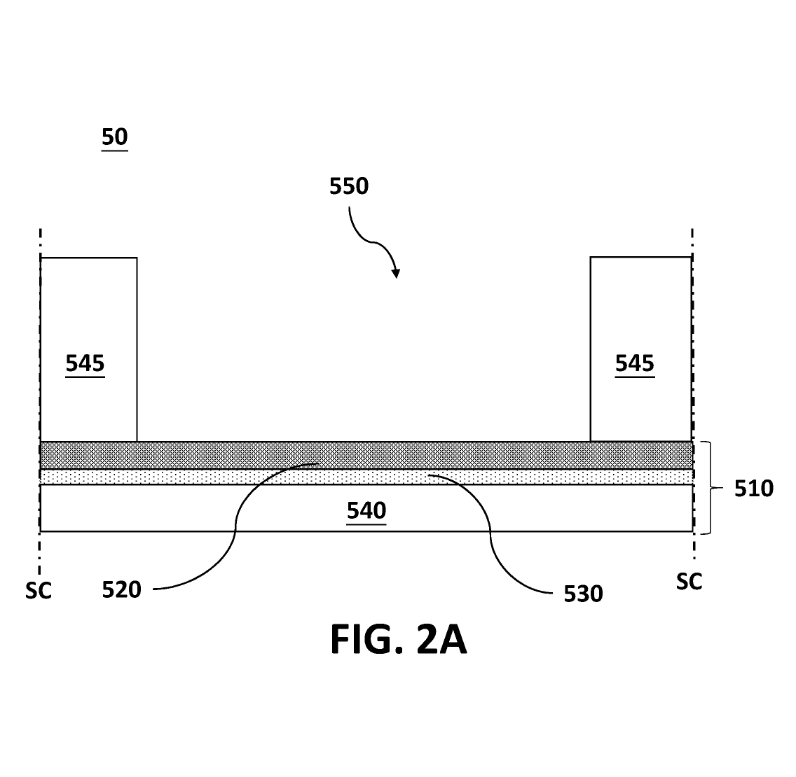

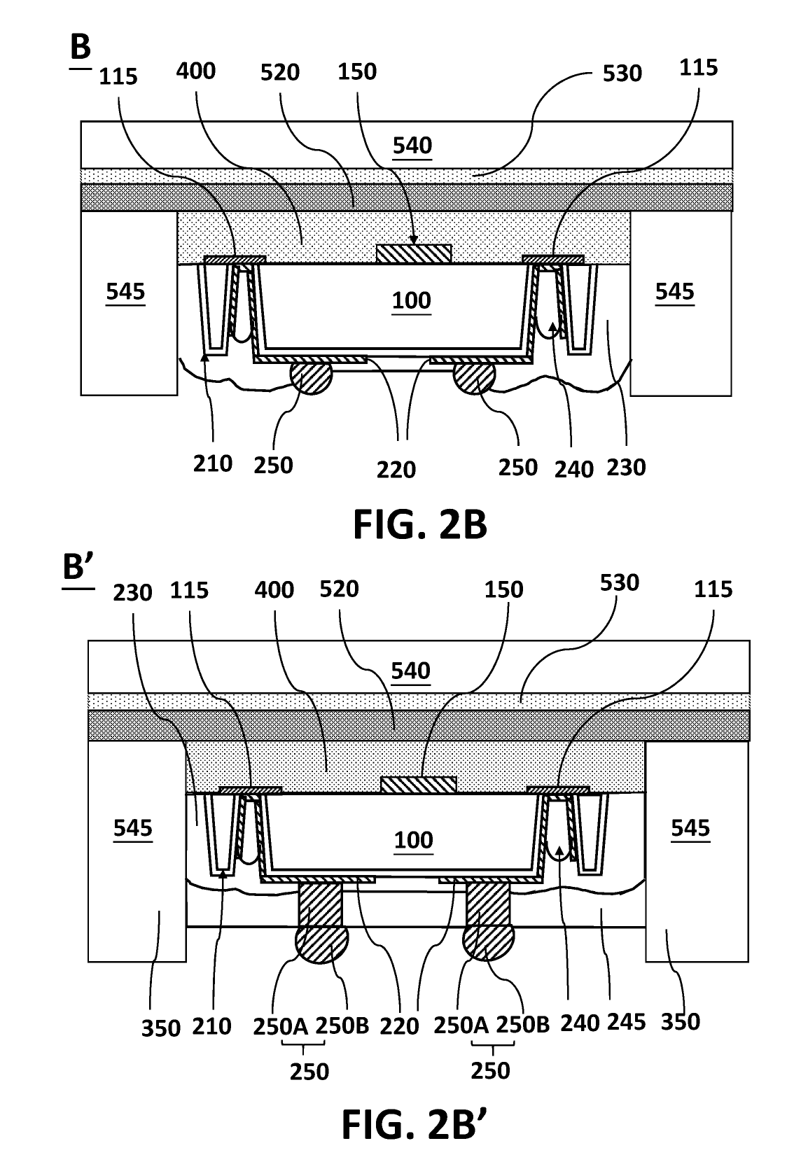

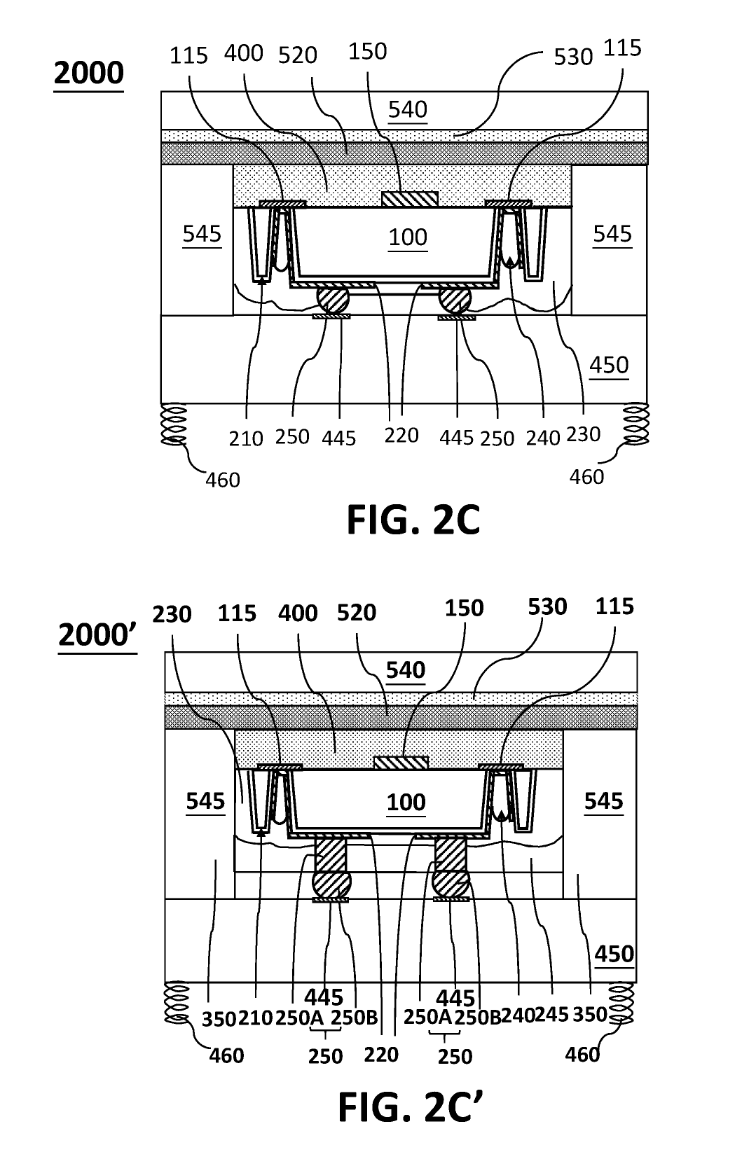

Embodiment 2 disclosing a method of manufacturing a chip scale sensing chip package module according to this invention will be described below accompanying with FIGS. 2A˜2C and FIGS. 2B′˜2C′.

FIG. 2A is a cross-sectional view of the bonding area 50 formed on the touch plate wafer. As shown in FIG. 2A, the bonding area 50 includes a base 510 and a spacer 540 surrounding the base 510. The spacer 545 has a cavity 550 exposing the surface of base 510, and the cavity 550 includes a bottom wall 330a and a side wall 330b surrounding the bottom wall 330a. The base 510 includes a touch pad 540, a color layer 520 and a second adhesive 530 sandwiched therebetween. The spacer layer 545 is formed on the color layer 520.

Next, referring to FIG. 2B and FIG. 2B′, the chip scale sensing chip 10 as shown in FIG. 1C or the chip scale sensing chip 10′ as shown in FIG. 1C′ is bond to the exposed color layer 520 formed on the bottom of the cavity 550 of the bonding area 50 by sandwiched a first adhesive 400 therebetween. A plurality of individual chip scale sensing chip packages B or B′ as shown in FIG. 2B or FIG. 2B′ can be generated by scribing the touch plate wafer along the scribing lines SC outside of the bonding areas 50.

Next, referring to FIG. 2C and FIG. 2C′, a print circuit board 450 as shown in FIG. 1E is provided, and the chip scale sensing chip package B or B′ generated according to above-mentioned process is bonded to the conductive bonding pads 445 of the print circuit board 450 by the conductive structures of B or B′ to form a chip scale sensing chip package module 2000 or 2000′.

Moreover, other electronic devices like a triggering device (not shown) which triggers the sensing chip 10 or 10′ to start can also be formed on the color later 350 formed on the bottom of the cavity 550 of each bonding area 50 and electrically connected to the sensing chips 10 or 10′.

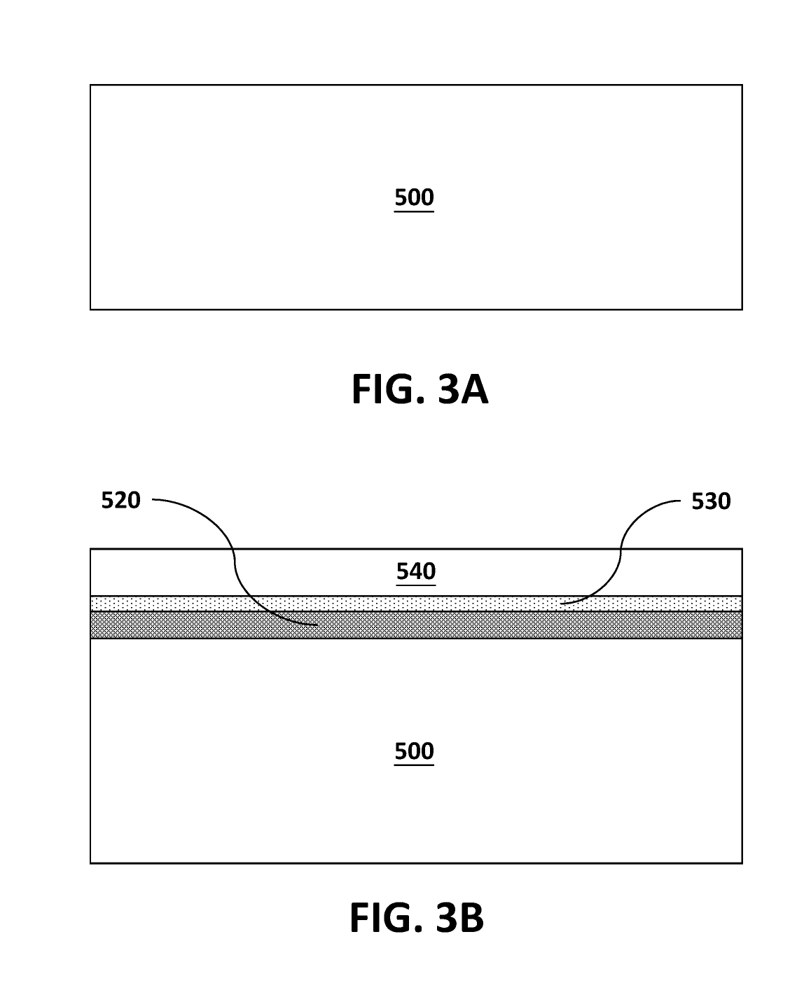

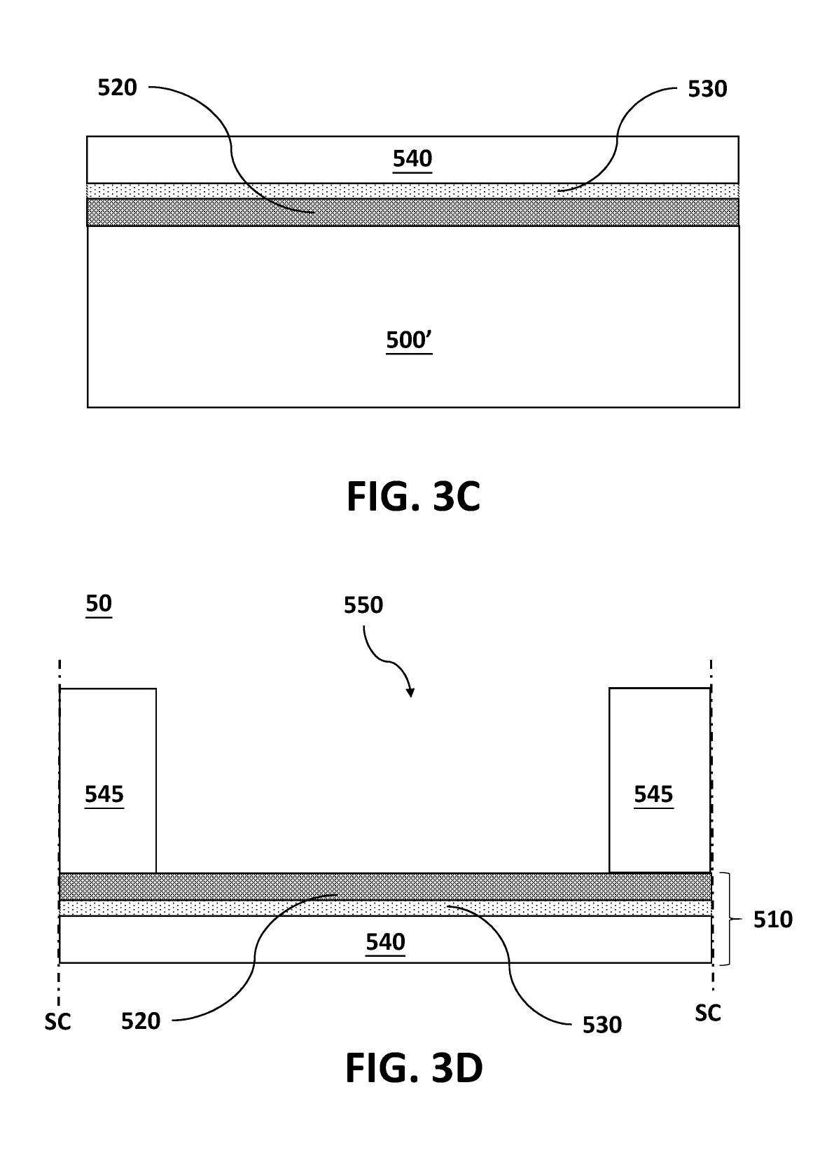

The steps of manufacturing the above-mentioned bonding areas 50 will be described in FIG. 3A˜FIG. 3D. As shown in FIG. 3A, a touch plate wafer 500 selected from a material comprising silicon or glass is provided. Next, referring to FIG. 3B, a color layer 520, a second adhesive 530, and a touch plate 540 are formed on the second top surface (not shown) of the touch plate wafer 500 in series. The touch plate wafer 500 of this embodiment can be selected from a material comprising transparent glass or silicon wafer, and the touch plate 540 can be selected from a transparent material with a hardness higher than 7 such as glass, sapphire or silicon nitride.

Next, the second bottom surface (not shown) of the touch plate wafer 500 is thinning by etching, milling, gridding or polishing to generate a thinner touch plate wafer 500′ as shown in FIG. 3C.

Next, referring to FIG. 3D, the thinned second bottom surface (not shown) of the touch plate wafer 500′ is patterned by etching or milling to form a plurality of bonding areas 50 spaced by each other. Each bonding area 50 comprises a base 510 and a spacer 545 formed on the base 510, and each base 510 comprises a touch pad 540, a color layer 520 and a second adhesive 530 sandwiched therebetween. The spacer 545 is formed on the color layer 520, and the spacer 545 has a cavity 550 exposing the color layer 520.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip scale sensing chip package module, comprising:
a chip scale sensing chip package, comprising:
a sensing chip with a first top substrate and a first bottom substrate opposite to the first top substrate, wherein the sensing chip has a sensing device and a plurality of conductive pads adjacent to the first top substrate, and a plurality of conductive structures connected to the conductive pads by a re-distribution layer adjacent to the first bottom surface;
a touch plate having a color layer, comprising a base and a spacer formed on the base, wherein the spacer has a cavity with a bottom wall exposing part of the surface of the base and a side wall surrounding the bottom wall; and
a first adhesive layer sandwiched between the sensing chip and the touch plate to join the first top surface of the sensing chip to the bottom wall of the cavity of the touch plate and surround the sensing chip by the side wall of the cavity; and
a print circuit board placed under the chip scale sensing chip package by bonding the conductive structure of the chip scale sensing chip package to the print circuit board.

2. The chip scale sensing chip package module as claimed in claim 1, wherein the area of the touch plate is greater than that of the sensing chip.

3. The chip scale sensing chip package module as claimed in claim 1, wherein the top-viewing profile of the cavity is rectangular and the top-viewing profile of the touch plate is circular.

4. The chip scale sensing chip package module as claimed in claim 1, wherein the thickness of the spacer is 10-folds of that of the base.

5. The chip scale sensing chip package module as claimed in claim 1, wherein the color layer is coated on the side wall and the bottom wall of the cavity.

6. The chip scale sensing chip package module as claimed in claim 1, wherein the base and the spacer are consisted of a material comprising glass.

7. The chip scale sensing chip package module as claimed in claim 1, wherein the base comprises a touch plate, a color layer and a second adhesive sandwiched between the touch plate and the color layer, and the spacer is formed on the color layer.

8. The chip scale sensing chip package module as claimed in claim 1, wherein the base and the touch plate are consisted of a material comprising glass, and the spacer is consisted of a material comprising glass or silicon.

9. The chip scale sensing chip package module as claimed in claim 1, wherein the first adhesive is consisted of a low-K or medium-K dielectric material.

10. The chip scale sensing chip package module as claimed in claim 1, wherein the conductive structures are selected from a group of solder balls, solder bumps, and conductive pillars, and mixtures thereof.

11. The chip scale sensing chip package module as claimed in claim 1, wherein the sensing device is selected from a group of a touch device, a biometric identification device and an environmental factors sensing device, and mixtures thereof.

12. The chip scale sensing chip package module as claimed in claim 1, wherein the biometric recognition device comprises a fingerprint identification device.

13. The chip scale sensing chip package module as claimed in claim 1, further comprising a buffer apparatus placed on the bottom of the print circuit board.

14. The chip scale sensing chip package module as claimed in claim 1, wherein the buffer apparatus comprises a spring or a spring button.

15. The chip scale sensing chip package module as claimed in claim 1, further comprising a trigger device formed within the cavity of the chip scale sensing chip package and electrically connected to the sensing chip.

16. A method of manufacturing a chip scale sensing chip package module, comprising the steps of:
providing a plurality of chip scale sensing chips, each chip scale sensing chip comprising a first top substrate and a first bottom substrate opposite to the first top substrate, wherein the sensing chip has a sensing device and a plurality of conductive pads adjacent to the first top substrate, and a plurality of conductive structures connected to the conductive pads by a re-distribution layer adjacent to the first bottom surface;
providing a touch plate wafer having a color layer and a plurality of bonding areas spaced with scribing lines, and each of the bonding areas having a base and a spacer formed on the base, wherein the spacer has a cavity with a bottom wall exposing part of the surface of the base and a side wall surrounding the bottom wall; and
providing a first adhesive layer to join the first top surface of each sensing chip to the bottom wall of each cavity and surround each sensing chip by each side wall of the cavities;
applying a scribing process along the scribing lines to generate a plurality of chip scale sensing chip package; and
providing a print circuit board. and bonding one of the chip scale sensing chip packages to the print circuit board by the conductive structures.

17. The method for manufacturing a chip scale sensing chip package module as claimed in claim 16, wherein the area of the touch plate is greater than that of the sensing chip.

18. The method for manufacturing a chip scale sensing chip package module as claimed in claim 16, wherein the top-viewing profile of the cavity is rectangular and the top-viewing profile of the touch plate is circular.

19. The method for manufacturing a chip scale sensing chip package module as claimed in claim 16, wherein the thickness of the space is 10-folds of that of the base.

20. The method for manufacturing a chip scale sensing chip package module as claimed in claim 16, wherein the color layer is coated on the side wall and the bottom wall of the cavity.

21. The method for manufacturing a chip scale sensing chip package module as claimed in claim 16, wherein the base and the spacer are consisted of a material comprising glass.

22. The method for manufacturing a chip scale sensing chip package module as claimed in claim 16, wherein the steps of manufacturing the touch plate wafer having a color layer comprise:
providing a touch plate wafer with a second top surface and a second bottom surface opposite to the second top surface;
coating a color layer on the top surface of the touch plate wafer;
coating a second adhesive layer on the color layer;
bonding a touch plate to the second adhesive layer;
thinning the second bottom surface of the touch plate wafer; and
pattering the thinned second bottom surface of the touch plate wafer to form a plurality of bonding areas spaced by scribing lines, and each bonding area comprising a base and a spacer formed on the base, wherein each base has a touch plate, a color layer and a second adhesive layer sandwiched between the touch plate and the color layer, and the spacer is formed on the color layer and has a cavity exposing the color layer.

23. The method for manufacturing a chip scale sensing chip package module as claimed in claim 22, wherein the base and the touch plate are consisted of a material comprising glass, and the spacer is consisted of a material comprising glass or silicon.

24. The method for manufacturing a chip scale sensing chip package module as claimed in claim 16, wherein the first adhesive is consisted of a low-K or medium-K dielectric material.

25. The method for manufacturing a chip scale sensing chip package module as claimed in claim 16, wherein the conductive structures are selected from a group of solder balls, solder bumps, and conductive pillars, and mixtures thereof.

26. The method for manufacturing a chip scale sensing chip package module as claimed in claim 16, wherein the sensing device is selected from a group of a touch device, a biometric identification device and an environmental factors sensing device, and mixtures thereof.

27. The method for manufacturing a chip scale sensing chip package module as claimed in claim 26, wherein the biometric recognition device is a fingerprint identification device.

28. The method for manufacturing a chip scale sensing chip package module as claimed in claim 16, further comprising a step of forming a buffer apparatus on the bottom of the print circuit board.

29. The method for manufacturing a chip scale sensing chip package module as claimed in claim 16, wherein the buffer apparatus comprises a spring or a spring button.

30. The chip scale sensing chip package module as claimed in claim 16, further comprising a step of forming a trigger device within the cavity of the chip scale sensing chip package and electrically connected to the sensing chip.
